(19) United States
(12) Patent Application Publication
(10) Pub. No.: US 2006/0166494 A1
(43) Pub. Date: Jul. 27, 2006

(54) Method of manufacturing a semiconductor device that includes a contact plug

(76) Inventor: Seong-Soo Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/335,215

(22) Filed: Jan. 18, 2006

(30) Foreign Application Priority Data
Jan. 21, 2005 (KR) 2005-05676

(51) Int. Cl. H01L 21/4763

(52) U.S. Cl. 438/639; 438/675

(57) ABSTRACT

A method of manufacturing a semiconductor device including a contact plug includes forming an insulation interlayer pattern and a protection pattern for protecting the insulation interlayer pattern using a mask pattern. The insulation interlayer includes a contact hole through which a surface of the substrate is partially exposed. A spacer is formed on a sidewall of the contact hole, and a first conductive layer is formed to a sufficient thickness to fill up the contact hole. The first conductive layer makes contact with the substrate at the exposed surface thereof. A contact plug is formed in the contact hole by removing the first conductive layer until a top surface of the insulation interlayer pattern is exposed. Accordingly, a contact failure between the contact plug and a conductive pattern adjacent to the contact plug is prevented.

### CROSS REFERENCE TO RELATED APPLICATIONS

This application claims priority from Korean Patent Application No. 10-2005-0005676 filed on 21 Jan. 2005. Korean Patent Application No. 10-2005-0005676 is incorporated by reference in its entirety.

### BACKGROUND

1. Technical Field

This disclosure relates to a method of manufacturing a semiconductor device, and more particularly, to a method of manufacturing a semiconductor device that includes a contact plug.

2. Description of the Related Art

Recently, as information media such as computers are widely used, a semiconductor devices are required to have higher data transfer rate, and many more memory cells must be integrated in a unit chip.

Accordingly, as design rules for semiconductor devices gradually decrease, metal wiring in the semiconductor device is formed into a multilayer wiring structure in which each metal wiring is vertically stacked on a substrate.

The multilayer wiring structure includes a lower conductive pattern, an upper conductive pattern and a contact plug for electrically connecting the lower and upper conductive patterns. An insulation interlayer is partially etched away, and a contact hole is formed through the insulation interlayer. A conductive material is filled into the contact hole, thereby forming a contact plug in the contact hole. Then, the lower conductive pattern formed below the insulation interlayer is electrically connected with the upper conductive pattern above the insulation interlayer through the contact plug.

A recent technological trend in a semiconductor device downsizes the space between the lower conductive pattern and the upper conductive pattern, so that a process margin for an overlap (overlap margin) between a conductive pattern and a contact plug also decreases. When the overlap margin is small, the conductive pattern and the contact plug are difficult to correctly align with each other, and the conductive pattern may be electrically connected with an adjacent contact plug, thereby generating a contact failure.

FIG. 1 is a sectional diagram illustrating a conventional multilayer wiring structure.

Referring to FIG. 1, when a contact hole 14 is formed on a substrate 10 by a dry etching process and a cleaning process, an entrance portion of the contact hole 14 is larger than a bottom portion of the contact hole 14. Further, a corner portion C of the insulation interlayer 12 is rounded at the entrance portion of the contact hole 14, so that a size of the contact hole 14 is much larger at the entrance portion than at the bottom portion.

For the rounded corner portion C of the contact hole 14, a little misalignment between a conductive pattern 18 and a contact plug 16 causes a contact failure 20 in which the contact plug 16 is electrically connected with both adjacent conductive patterns 18, thereby generating a short circuit.

Furthermore, a portion of a sidewall of the contact hole 14 is also removed during the cleaning process after an anisotropic etching process for forming the contact hole 14, so that a size of the contact hole 14 is enlarged. That is, the size of the contact hole 14 is difficult to control due to the cleaning process. When the size of the contact hole 14 is overly enlarged, both neighboring contact plugs adjacent to each other are electrically connected with each other, thereby generating a contact failure.

An example of a method of forming a contact plug is disclosed in Japanese Laid-Open Publication Patent No. 2000-232093. According to this publication, a contact hole is formed using a polysilicon pattern having a sidewall as a mask and the contact hole is filled with a conductive material, thereby forming a contact plug. The contact hole may be downsized due to the sidewall of the polysilicon pattern.

However, if this method is followed, the polysilicon pattern is somewhat etched away during an etching process against an insulation interlayer in accordance with an etching ratio, and an entrance portion of the contact hole is still enlarged. In addition, a sidewall of the contact hole is still removed during the cleaning process after the etching process.

Embodiments of the invention address these and other disadvantages of the conventional art.

### SUMMARY

According to embodiments of the invention, a method of manufacturing a semiconductor device is capable of preventing short circuits in a multilayer wiring structure in the semiconductor device.

### BRIEF DESCRIPTION OF THE DRAWINGS

The above and other features and advantages of the invention will become readily apparent by reference to the following detailed description when considering in conjunction with the accompanying drawings, in which:

FIG. 1 is a sectional diagram illustrating a conventional multilayer wiring structure;

FIGS. 2 to 9 are sectional diagrams illustrating processing steps for a method of manufacturing a semiconductor device according to some embodiments of the invention; and

FIGS. 10 to 14 are sectional diagrams illustrating processing steps for a method of manufacturing a semiconductor device according to other embodiments of the invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to sectional diagrams that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

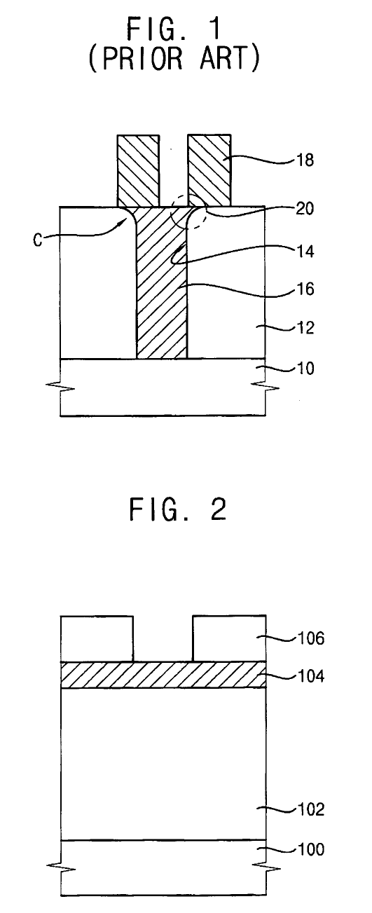

FIGS. 2 to 9 are sectional diagrams illustrating processing steps for a method of manufacturing a semiconductor device according to some embodiments of the invention.

Referring to FIG. 2, a device isolation layer (not shown) is formed on a portion of a semiconductor substrate 100, thereby defining an active region in which conductive structures are formed and a field region for isolating the active regions.

An insulation interlayer 102 comprising silicon oxide is formed on the substrate 100. Semiconductor structures such as a metal oxide semiconductor (MOS) transistor, a metal wiring and a logic device are formed on the substrate 100.

A protection layer 104 is formed on the insulation interlayer 102 for protecting the insulation interlayer 102 in a subsequent etching process, so that an un-etched portion of the insulation interlayer is prevented from being etched in the etching process. An etching rate of the protection layer 104 is different from that of the insulation interlayer 102, and in the illustrated embodiments, the protection layer 104 has an etching selectivity with respect to the insulation interlayer 102 at particular etching conditions.

The protection layer 104 is formed by depositing a conductive material onto a surface of the insulation interlayer 102, and preferably, the protection layer comprises the same conductive material as a first conductive layer that is formed in a subsequent process. Examples of the protection layer 104 include a polysilicon layer and a metal layer that is to be patterned by a photolithography process. In the illustrated embodiments, the protection layer comprises polysilicon.

The thickness of the protection layer 104 should be greater than a thickness of an insulation layer for forming a spacer on a sidewall of a contact hole in order to protect the un-etched portion of the insulation interlayer 102 in a subsequent etching process. The thickness of the protection layer 104 is discussed in further detail below.

A photoresist pattern 106 is formed on the protection layer 104, so that a top surface of the protection layer 104 is partially exposed through the photoresist pattern 106 to form the contact hole.

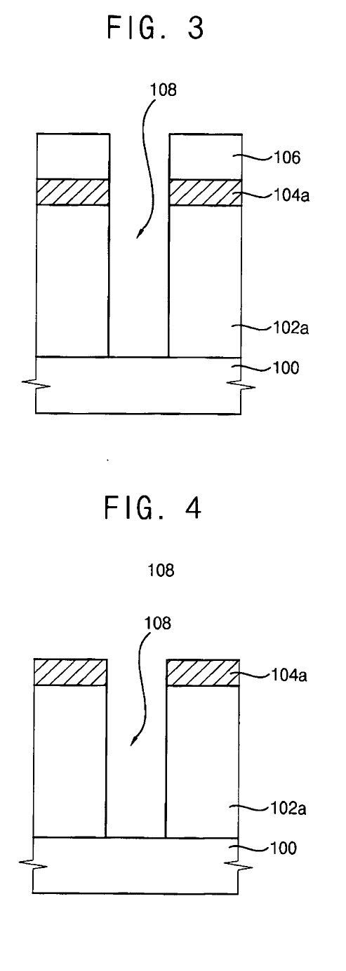

Referring to FIG. 3, the protection layer 104 is anisotropically etched away using the photoresist pattern 106 as an etching mask, thereby forming a protection pattern 104a on the insulation interlayer 102. The insulation interlayer 102 is sequentially and anisotropically etched away using the photoresist pattern 106 as an etching mask, thereby forming a contact hole 108 through which a top surface of the substrate 100 is partially exposed. Hereinafter, the insulation interlayer 102 including the contact hole 108 is referred to as insulation interlayer pattern 102a. The exposed portion of the substrate 100 may be a source/drain region or a lower wiring in a semiconductor device.

In the illustrated embodiments, an etching process using the photoresist pattern 106 as an etching mask removes the insulation interlayer 102 as well as the protection layer 104, so that the protection layer 104 is not used as an etching mask for an etching process against the insulation interlayer 102. Accordingly, the protection layer 104 under the photoresist pattern 106 is not removed or damaged in the above etching process.

Referring to FIG. 4, the photoresist pattern 106 is removed from the protection pattern 104a by at least one of an ashing process and a strip process, thereby exposing the protection pattern 104a.

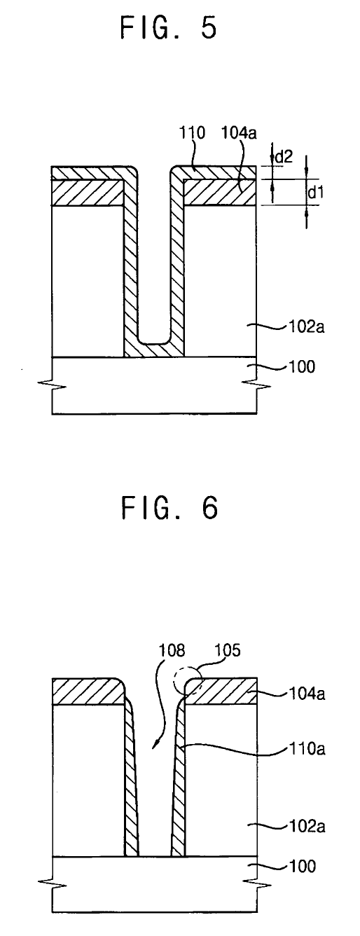

Referring to FIG. 5, an insulation layer 110 is formed on a top surface of the protection pattern 104a, on sidewalls of the contact hole 108 and on the surface of the substrate 100 exposed through the contact hole 108.

The insulation layer 110 prevents the sidewall of the contact hole 108 from being removed in a subsequent cleaning process, so that the insulation layer 110 has a sufficient thickness to cover the sidewall of the contact hole 108 in the cleaning process without completely filling up the contact hole 108. That is, the insulation layer 110 has a sufficient thickness such that the sidewall of the contact hole 108 is still covered with the insulation layer 110 even though the insulation layer 110 is removed from a bottom portion of the contact hole 108 in the subsequent cleaning process. In the illustrated embodiments, a thickness d2 of the insulation layer 110 is less than a thickness d1 of the protection pattern 104a.

The insulation layer 110 needs to be removed without removing any neighboring layers making contact with the insulation layer 110, so an etching rate of the insulation layer 110 should be different from that of the insulation interlayer pattern 102a and the protection pattern 104a. In the illustrated embodiments, the insulation layer 110 has an etching rate that is greater than that of the insulation interlayer pattern 102a and the protection pattern 104a. For example, the insulation layer 110 may comprise a material such as silicon nitride or silicon oxynitride.

Referring to FIG. 6, the insulation layer 110 is anisotropically etched away, so that a spacer is formed on the sidewalls of the contact hole 108 and the top surface of the substrate 100 is again exposed through the contact hole 108.

A corner portion 105 of the protection pattern 104a around an upper portion of the contact hole 108 is etched away at a higher etching rate than a top surface of the protection pattern 104a and is formed into a rounded shape.

However, the insulation interlayer pattern 102a underlying the protection pattern 104a is protected in the anisotropic etching process and the corner portion of the insulation interlayer pattern 102a is prevented from being etched in the etching process. As a result, the corner portion of the insulation interlayer pattern 102a still remains unchanged despite the etching process against the insulation layer 110 and is not formed into a rounded shape.

In particular, because the protection pattern 104a is thicker than the insulation layer 110, the spacer 110a is formed on a whole sidewall of the contact hole 108, so that an upper portion of the insulation interlayer pattern 102a, which defines a size of the entrance portion of the contact hole 108, is not removed in the etching process.

Accordingly, the spacer 110a is formed on the sidewall of the contact hole 108 without increasing the size of the entrance portion of the contact hole 108.

A cleaning process is performed after completing the etching process, so that a residual resistant material on the bottom portion of the contact hole 108, for example, a native oxide, is removed from the substrate 100. A diluted aqueous hydrogen fluoride (HF) solution may be used as a cleaning solution for the cleaning process.

A silicon oxide layer is somewhat etched away in the above cleaning process because the cleaning process is performed for removing the native oxide. However, the spacer 110a prevents the cleaning solution from permeating into the sidewall of the contact hole 108, so that the sidewall of the contact hole 108 remains unaffected during the cleaning process. Accordingly, the size of the contact hole 108 is not enlarged, thereby preventing the contact failure between contact plugs adjacent to each other in a subsequent process.

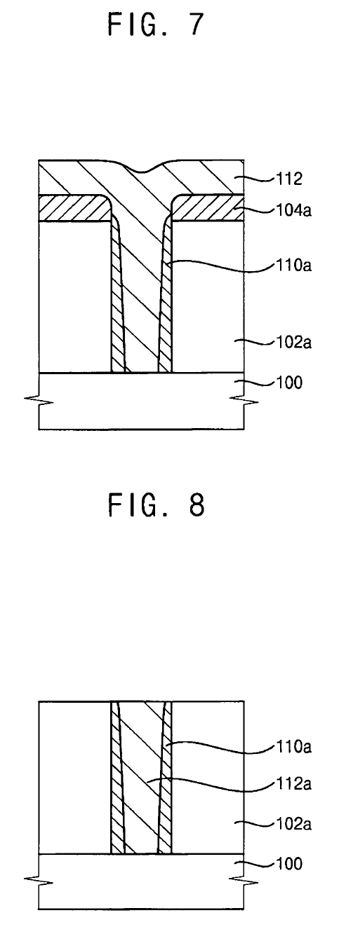

Referring to FIG. 7, a first conductive layer 112 is formed on the protection pattern 104a to a sufficient thickness to fill up the contact hole 108, so that the first conductive layer 112 makes contact with the substrate 100 at the exposed surface. In the illustrated embodiments, the first conductive layer 112 comprises the same material as the protection pattern 104a, so that the first conductive layer 112 and the protection pattern 104a are removed at the same rate in a subsequent planarizing process. The first conductive layer 112 may comprise polysilicon.

Referring to FIG. 8, the first conductive layer 112 and the protection pattern 104a are removed until a top surface of the insulation interlayer pattern 102a is exposed, thereby forming a contact plug 112a in the contact hole 108. The contact plug 112a makes contact with the substrate 100 in the contact hole 108. Accordingly, the protection pattern 104a is completely removed and the first conductive layer 112 is partially removed due to the planarization process against the first conductive layer 112 and the protection pattern 104a.

At least one of a chemical mechanical polishing (CMP) process and a dry etching process may be performed for planarizing the first conductive layer 112 and the protection pattern 104a. In the illustrated embodiments, the CMP process is firstly performed on a top surface of the first conductive layer 112, so that the first conductive layer 112 and the protection pattern 104a are partially removed. Thereafter, the dry etching process is performed on the top surface of the protection pattern 104a, so that the protection pattern 104a is completely removed from the insulation interlayer pattern 104a and the conductive layer 112 remains only in the contact hole 108, thereby forming the contact plug 112a in the contact hole 108.

According to the illustrated embodiments, the corner portion of the insulation interlayer pattern 102a is not rounded at the upper portion of the contact hole 108, so that the size of the upper portion of the contact hole 108 is substantially identical to that of the lower portion of the contact hole 108.

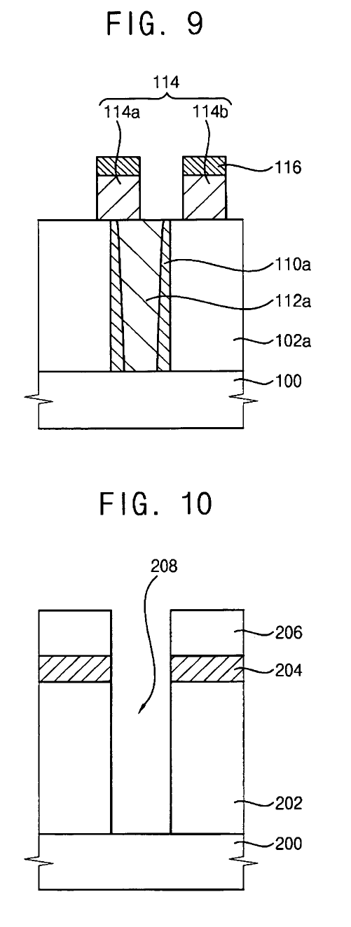

Referring to FIG. 9, a second conductive layer (not shown) is formed on the contact plug 112a and the insulation interlayer pattern 102a. The second conductive layer may be a single layer or a multilayer including single layers sequentially stacked on the contact plug 112a and the insulation interlayer pattern 102a. The single layer includes a polysilicon layer, a metal silicide layer, or a metal layer.

In the illustrated embodiments, the second conductive layer includes a tungsten layer because the tungsten layer is patterned by an anisotropic etching process and has an electrical resistance lower than that of the polysilicon layer.

A mask layer (not shown) is formed on the second conductive layer and patterned by a photolithography process, thereby forming a hard mask pattern 116 on the second conductive layer.

The second conductive layer is etched away using the hard mask pattern 116 as an etching mask, thereby forming a conductive pattern 114 linearly extending on the contact plug 112a and the insulation interlayer pattern 102a. As illustrated in FIG. 9, the portion of the conductive pattern 114 that is in contact with the contact plug 112a is referred to as a first pattern 114a and the portion of the conductive pattern 114 that is not in contact with the contact plug 112a but is in contact with the insulation interlayer pattern 102a and adjacent to the first pattern 114a is referred to as second pattern 114b.

According to the illustrated embodiments, a size of an upper portion of the contact plug 112a is substantially identical to that of a lower portion of the contact plug 112a, so that a relatively small misalignment of the conductive pattern may be prevented from causing a contact failure in which the second pattern 114b makes contact with the contact plug 112a. Furthermore, a sufficient bridge margin between the second pattern 114b and the contact plug 112a may be obtained even though the first pattern 114a makes contact with a peripheral portion of the contact plug 112a.

FIGS. 10 to 14 are sectional diagrams illustrating processing steps for a method of manufacturing a semiconductor device according to other embodiments of the invention.

Referring to FIG. 10, a device isolation layer (not shown) is formed on a portion of a semiconductor substrate 200, thereby defining an active region in which conductive structures are formed and a field region for isolating the active regions.

An insulation interlayer (not shown) exemplarily comprising a silicon oxide is formed on the substrate 200. Semiconductor structures such as a metal oxide semiconductor (MOS) transistor, a metal wiring and a logic device are formed on the substrate 200.

A protection layer (not shown) is formed on the insulation interlayer for protecting the insulation interlayer in a subsequent etching process, so that an un-etched portion of the insulation interlayer is prevented from being etched in the etching process. In the present embodiment, the protection layer has an etching selectivity with respect to the insulation interlayer, and comprises silicon nitride.

A thickness of the protection layer is greater than a thickness of the insulation layer for protecting the un-etched portion of the insulation interlayer in a subsequent etching process for forming a spacer on a sidewall of a contact hole.

A photoresist pattern 206 is formed on the protection layer, so that a top surface of the protection layer is partially exposed through the photoresist pattern 206.

The protection layer is anisotropically etched away using the photoresist pattern 206 as an etching mask, thereby forming a protection pattern 204 on the insulation interlayer. Thereafter, the insulation interlayer is sequentially and anisotropically etched away using the photoresist pattern 206 as an etching mask, thereby forming a contact hole 208 through which a top surface of the substrate 200 is partially exposed. The insulation interlayer including the contact hole 208 is referred to as an insulation interlayer pattern 202.

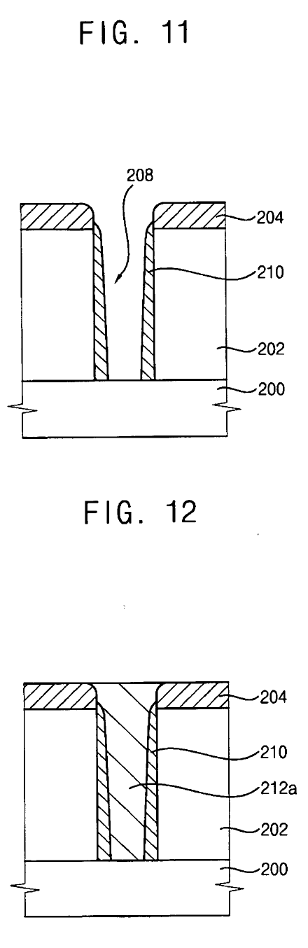

Referring to FIG. 11, the photoresist pattern 206 is removed from the protection pattern 204 by at least one of an ashing process and a strip process, thereby exposing the protection pattern 204.

An insulation layer (not shown) is formed on a top surface of the protection pattern 204, on sidewalls of the contact hole 208 and on the surface of the substrate 200 exposed through the contact hole 208. In the illustrated embodiments, a thickness of the insulation layer is less than a thickness of the protection pattern 204. The insulation layer needs to be removed without any removal of neighboring layers making contact with the insulation layer, so that an etching rate of the insulation layer needs to be different from that of the insulation interlayer pattern and the protection pattern 204. In the illustrated embodiments, the insulation layer has an etching rate higher than that of the insulation interlayer pattern 202.

The insulation layer comprises the same material as the protection pattern 204, and in the illustrated embodiments, comprises silicon nitride.

The insulation layer is anisotropically etched away, so that a spacer 210 is formed on the sidewalls of the contact hole 208 and the top surface of the substrate 200 is again exposed through the contact hole 208.

A corner portion of the protection pattern 204 around an upper portion of the contact hole 208 is etched away at a higher etching rate than a top surface of the protection pattern 204 and is formed into a rounded shape. However, the insulation interlayer pattern 202 underlying the protection pattern 204 is protected in the anisotropic etching process and the corner portion of the insulation interlayer pattern 202 is prevented from being etched in the etching process. As a result, the corner portion of the insulation interlayer pattern 202 remains unchanged despite the etching process against the insulation layer and does not take on a rounded shape.

A cleaning process is performed after completing the etching process, so that a residual resistant material on a bottom portion of the contact hole 208, for example, a native oxide, is removed from the substrate 200.

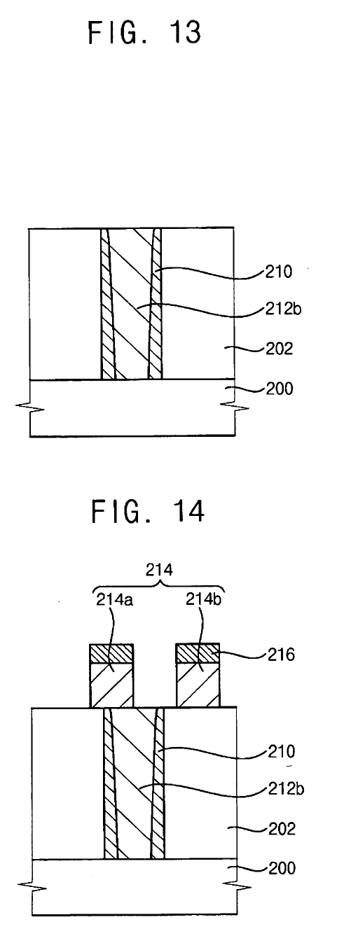

Referring to FIGS. 12 and 13, a first conductive layer (not shown) is formed on the protection pattern 204 to a sufficient thickness to fill up the contact hole 208, so that the first conductive layer makes contact with the exposed surface of the substrate 200. Examples of the first conductive layer include a polysilicon layer, a metal silicide layer and a metal layer. In the illustrated embodiments, the polysilicon layer is used as the first conductive layer.

Then, the first conductive layer and the protection pattern 204 are removed until a top surface of the insulation interlayer pattern 202 is exposed by a planarization process, thereby forming a contact plug 212b in the contact hole 208. At least one of a chemical mechanical polishing (CMP) process and a dry etching process may be performed for planarizing the first conductive layer and the protection pattern 204.

In the illustrated embodiments, a material of the first conductive layer is different from that of the protection pattern 204, so that the planarization process against the first conductive layer and the protection pattern 204 is performed in view of material characteristics of the first conductive layer and the protection pattern 204.

As an example of the planarization process, a CMP process may be performed twice, where each of the CMP processes has different operational characteristics. In particular, the first conductive layer is removed and planarized by a first CMP process until a top surface of the protection pattern 204 is exposed, thereby forming a preliminary contact plug 212a shown in FIG. 12. The first CMP process may be performed using a ceria slurry comprising cerium oxide (CeO₂). Thereafter, the preliminary contact plug 212a and the protection pattern 204 are removed and planarized by a second CMP process until a top surface of the insulation interlayer pattern 202 is exposed, thereby forming a contact plug 212b shown in FIG. 13. The second CMP process may be performed using silica slurry.

As another example of the planarization process, a CMP process and an etch-back process may be sequentially performed. In particular, the first conductive layer may be removed and planarized by a CMP process until a top surface of the protection pattern 204 is exposed, thereby forming a preliminary contact plug 212a shown in FIG. 12. The CMP process may be performed using ceria slurry comprising cerium oxide (CeO₂). Thereafter, front surfaces of the preliminary contact plug 212a and the protection pattern 204 are etched away until a top surface of the insulation interlayer pattern 202 by an etch-back process, thereby forming a contact plug 212b shown in FIG. 13. During the etch-back process, the protection pattern 204 and the preliminary contact plug 212a are etched away at almost the same rate.

Referring to FIG. 14, a second conductive layer (not shown) is formed on the contact plug 212b and the insulation interlayer pattern 202.

A mask layer (not shown) is formed on the second conductive layer and is patterned by a photolithography process, thereby forming a hard mask pattern 216 on the second conductive layer.

The second conductive layer is etched away using the hard mask pattern 216 as an etching mask, thereby forming a conductive pattern 214 that is disposed on the contact plug 212b and the insulation interlayer pattern 202. As illustrated in FIG. 14, the portion of the conductive pattern 214 that is in contact with the contact plug 212b is referred to as a first pattern 214a and the portion of the conductive pattern 214 that is not in contact with the contact plug 212a but is in contact with the insulation interlayer pattern 202 and is adjacent to the first pattern 214a is referred to as a second pattern 214b.

According to the illustrated embodiments, a size of an upper portion of the contact plug 212b is substantially identical to that of a lower portion of the contact plug 212a, so that small misalignments of the conductive pattern are prevented from causing a contact failure in which the second pattern 214b makes contact with the contact plug 212b. Further, a sufficient bridge margin between the second pattern 214b and the contact plug 212b may be obtained even though the first pattern 214a makes contact with a peripheral portion of the contact plug 212b.

According to embodiments of the invention, a contact failure between contact plugs adjacent to each other or between a contact plug and a conductive pattern neighboring the contact plug is remarkably reduced, thereby preventing electrical short due to the contact failure. Accordingly, operational failure is sufficiently reduced in a semiconductor device including the contact plug, thereby improving production yield and the reliability of devices.

The invention may be practiced in many ways. What follows are exemplary non-limiting descriptions of some embodiments of the invention.

According to some embodiments, a method of manufacturing a semiconductor device includes forming an insulation interlayer pattern and a protection pattern for protecting the insulation interlayer pattern using one mask pattern. The insulation interlayer includes a contact hole through which a surface of the substrate is partially exposed. A spacer is formed on a sidewall of the contact hole, and a first conductive layer is formed to a sufficient thickness to fill up the contact hole. The first conductive layer makes contact with the substrate at the exposed surface thereof. A contact plug is formed in the contact hole by removing the first conductive layer until a top surface of the insulation interlayer pattern is exposed.

According to other embodiments, a method of manufacturing a semiconductor device includes sequentially forming an insulation interlayer and a protection layer for protecting the insulation interlayer on a substrate. A photoresist pattern is formed on the protection layer. The protection layer and the insulation interlayer are partially etched away using the photoresist pattern as an etching mask, thereby forming a protection pattern and an insulation interlayer pattern including a contact hole through which a top surface of the substrate is exposed. A spacer is formed on a sidewall of the contact hole. A first conductive layer is formed to a sufficient thickness to fill up the contact hole, so that the first conductive layer makes contact with the substrate at the exposed surface thereof. A contact plug is formed by removing the first conductive layer until a top surface of the insulation interlayer pattern is exposed.

According to embodiments of the invention, a corner portion of the insulation interlayer pattern around an entrance portion of the contact hole is not etched away, and a size of the entrance portion of the contact hole is not enlarged. Accordingly, a size of an upper portion of the contact plug is not enlarged, thereby preventing contact failure between the contact plug and a contact pattern adjacent to the contact plug.

Furthermore, the spacer prevents the sidewall of the contact hole from being removed in the cleaning process. Accordingly, a size increase of the contact hole is minimized, thereby preventing contact failures between the contact plugs that are adjacent to each other.

Although some exemplary embodiments of the invention are described above, it is understood that the invention should not be limited to these exemplary embodiments, but that various changes and modifications can be made by one skilled in the art within the spirit and scope of the invention as defined by the following claims.

1. A method of manufacturing a semiconductor device, comprising:
forming an insulation interlayer pattern and a protection pattern on a substrate using a mask pattern, the insulation interlayer including a contact hole, the contact hole partially exposing a surface of the substrate;
forming a spacer on a sidewall of the contact hole;
filling the contact hole with a first conductive layer, the first conductive layer making contact with the surface of the substrate; and
partially removing the first conductive layer until a top surface of the insulation interlayer pattern is exposed to form a contact plug in the contact hole.

2. The method of claim 1, wherein forming the insulation interlayer pattern and the protection pattern comprises:
forming an insulation interlayer on the substrate;
forming a protection layer on the insulation interlayer;
forming a mask pattern on the protection layer;
etching the protection layer and the insulation interlayer using the mask pattern as an etching mask to form the insulation interlayer pattern and the contact hole; and
removing the mask pattern from the protection pattern.

3. The method of claim 2, wherein the mask pattern comprises photoresist material.

4. The method of claim 1, wherein the protection pattern comprises the same material as the first conductive layer.

5. The method of claim 4, wherein the first conductive layer comprises polysilicon.

6. The method of claim 1, wherein an etching rate of the protection pattern is different from that of the insulation interlayer pattern.

7. The method of claim 6, wherein the protection pattern comprises silicon nitride.

8. The method of claim 1, wherein the spacer has an etching rate different from the protection pattern.

9. The method of claim 1, wherein the spacer and the protection pattern comprise substantially the same material.

10. The method of claim 1, wherein forming the spacer comprises:
forming an insulation layer in contact with a top surface of the protection pattern, in contact with a sidewall of the contact hole, and in contact with the surface of the substrate; and
anisotropically etching the insulation layer to expose the surface of the substrate and to leave a portion of the insulation layer on the sidewall of the contact hole.

11. The method of claim 10, wherein a thickness of the insulation layer is less than a thickness of the protection pattern.

12. The method of claim 1, further comprising, before filling the contact hole with the first conductive layer, wet cleaning the contact hole and a top surface of the protection pattern.

13. The method of claim 1, wherein removing the first conductive layer comprises at least one selected from the group consisting of chemical mechanical polishing (CMP) and dry etching.

14. The method of claim 1, further comprising, after partially removing the first conductive layer:
forming a second conductive layer on the insulation interlayer pattern and the contact plug; and
partially etching the second conductive layer to form a conductive pattern that extends on the contact plug and the insulation interlayer pattern.

15. The method of claim 14, wherein the conductive pattern has a linear shape.

16. A method of manufacturing a semiconductor device, comprising:
forming an insulation interlayer on a substrate,
forming a protection layer for protecting the insulation interlayer on the insulation interlayer;
forming a photoresist pattern on the protection layer;
partially etching the protection layer and the insulation interlayer using the photoresist pattern as an etching mask to form a protection pattern, an insulation interlayer pattern, and a contact hole that exposes a top surface of the substrate;
forming a spacer on a sidewall of the contact hole;
filling up the contact hole with a first conductive layer; and
removing the first conductive layer until a top surface of the insulation interlayer pattern is exposed to form a contact plug, the contact plug in contact with the top surface of the substrate.

17. The method of claim 16, wherein forming the protection layer comprises depositing silicon nitride onto a surface of the insulation interlayer.

18. The method of claim 16, wherein forming the contact plug includes:
performing a CMP process until a portion of the protection pattern is removed, so that the first conductive layer and the protection pattern are partially removed; and
performing a dry etching process on a surface of a remaining portion of the protection pattern and the first conductive layer until the top surface of the insulation interlayer is exposed, so that the protection layer is removed from the insulation interlayer pattern and the first conductive layer only remains in the contact hole.

19. The method of claim 16, wherein removing the first conductive layer comprises:
performing a first CMP process on a surface of the conductive layer until a top surface of the protection pattern is exposed; and
performing a second CMP process on the top surface of the protection pattern and on a surface of the conductive pattern until the top surface of the insulation interlayer pattern is exposed.

20. The method of claim 16, wherein forming the protection layer comprises depositing polysilicon onto a top surface of the insulation interlayer.

21. The method of claim 16, further comprising, after removing the first conductive layer:
forming a second conductive layer on the insulation interlayer pattern and the contact plug; and
partially etching the second conductive layer to form a conductive pattern, a portion of the conductive pattern having a bottom surface in contact with the contact plug and the insulation interlayer pattern, another portion of the conductive pattern electrically isolated from the portion of the conductive pattern and having a bottom surface in contact only with the insulation interlayer pattern.
